(19) United States
(12) Patent Application Publication
(10) Pub. No.: US 2011/0268363 A1
(43) Pub. Date: Nov. 3, 2011

(54) METHOD FOR EVALUATING SUPERIMPOSITION OF PATTERN

(76) Inventors: Mayuka Osaki, Yokohama (JP); Chie Shishido, Kawasaki (JP)

(21) Appl. No.: 13/143,346

(22) PCT Filed: Dec. 10, 2009
(86) PCT No.: PCT/JP2009/006766

§ 371 Date: Jul. 6, 2011

(30) Foreign Application Priority Data
Jan. 30, 2009 (JP) 2009-019318

(51) Int. Cl. H01J 37/26; G06K 9/62

(52) U.S. Cl. 382/209; 250/310

(57) ABSTRACT

Provided is a method for evaluating superimposition of a pattern, wherein an alignment shift quantity and a shift direction can be evaluated at a discretionary position within an exposure shot. The method uses a superimposition evaluation pattern, and the image of the superimposition evaluation pattern is acquired (S1) using electron microscopes (10, 109), the shift quantity and direction in each exposure step are calculated (S2) by comparing the acquired image with layout information, which has been registered in a storage section (111) and is on the layout with which the superimposition evaluation pattern is to be arranged, and the evaluation results are displayed (S3).

### BACKGROUND OF THE INVENTION

1. Field of the Invention

The present invention relates to a method for evaluating overlay of fine patterns formed in the same region in different exposure steps.

2. Description of the Related Arts

In semiconductor fabrication processes, the overlay accuracy between patterns in the layers above and below is an important evaluation item that influences the performance of semiconductor devices in forming fine patterns (semiconductor patterns) on various thin films in multiple layers.

Conventionally, as described in Japanese Patent Application Laid-Open Publication No. H06-202311, in overlay evaluation between patterns in the layers above and below, the optical image of an overlay evaluation pattern, which is formed in advance on a wafer, is acquired for evaluating the amount of misalignment between the individual layers by image analysis. In order to obtain sufficient overlay evaluation accuracy according to this method, it is necessary to acquire an optical image with adequate resolution. Concerning this, with semiconductor patterns becoming finer in these years, demanded overlay evaluation accuracy also becomes severe, causing a difficulty that the resolution of an acquirable optical image provides demanded overlay evaluation accuracy.

As a means for addressing this problem, such a method is used as described in Japanese Patent Application Laid-Open Publication No. 2001-272207 that spectral waveforms of an overlay evaluation pattern, which is formed in advance on a wafer, are acquired for calculating the amount of misalignment between individual layers by waveform analysis. This method is used to acquire sufficient overlay evaluation accuracy.

### PRIOR ART DOCUMENTS

### Patent References

Patent reference 1: Japanese Patent Application Laid-Open Publication No. H06-202311
Patent reference 2: Japanese Patent Application Laid-Open Publication No. 2001-272207

### SUMMARY OF THE INVENTION

For the techniques of forming finer patterns, the development and practical use of double patterning (DP) are advancing in which patterns are formed on the same layer in different exposure steps for implementing high density patterns. A double exposure technique, which is one of double patterning techniques, will be described with reference to FIGS. 10A to 10E. First, a resist is coated on a lower layer film 1001 formed on a wafer (substrate) 1000 to form a first resist film 1002 (FIG. 10A), and this first resist film 1002 is exposed and developed to form a resist pattern 1002a with a first-time exposure (FIG. 10B). Subsequently, this resist pattern 1002a is frozen and treated so as not to be exposed to light with a second-time exposure (FIG. 10C). A resist for second-time exposure is coated thereon to form a second resist film 1003 (FIG. 10D), and a resist pattern 1003a is formed with a second-time exposure in the space between patterns formed with the first-time exposure (FIG. 10E). With the use of the method described above, it is possible to form resist patterns at a pitch that is a half of the minimum pitch at which resist patterns can be formed with a single exposure.

With the practical use of this technique, overlay evaluation is necessary not only for the misalignment of patterns between the layers above and below but also for patterns formed on the same layer in different exposure steps. However, the overlay evaluation method by spectral waveforms analysis in Japanese Patent Application Laid-Open Publication No. 2001-272207 has a problem in that it is not possible to identify the patterns in the individual exposure steps in the case of evaluating the overlay of the patterns in the same layer, although it is possible to identify the patterns in the layers above and below; it is possible to evaluate the amount of relative misalignment, but it is not possible to evaluate the direction of misalignment. In other words, it is not possible to properly feed back evaluated results to the exposure process for correcting misalignments.

In addition, with patterns becoming finer, demands for overlay accuracy become severe as well as mask fabrication error, distortion in a shot in exposure (in a region that is exposed with a single photoirradiation exposure in which a chip or a few chips are exposed with a single shot), or the like are not ignorable, causing a necessity for overlay evaluation in plural points in an exposure shot in addition to the misalignment of the overall mask at each exposure shot. In overlay evaluation according to Japanese Patent Application Laid-Open Publication No. 2001-272207, it is necessary to use an evaluation only pattern formed in advance. Because this evaluation only pattern has to be a repeat pattern in a region of a few microns at the minimum, it is not realistic that dedicated patterns are distributed at a plurality of places in a shot. For this reason, the conventional overlay evaluation methods have a problem in that it is not possible to perform overlay evaluation at given positions in an exposure shot.

It is an object of the present invention to provide a method for evaluating overlay that can evaluate the amount and direction of misalignment at given positions in an exposure shot.

An aspect for implementing the aforementioned object is a method for evaluating overlay of patterns using a first pattern formed on a sample in a first exposure step and a second pattern formed on the sample in a second exposure step, the method including the steps of: registering, in a database, layout information about the first pattern and the second pattern to be arranged; acquiring an image of the first pattern and the second pattern formed on the sample with a charged particle microscope; and comparing the layout information registered in the database with the image and determining a misalignment amount and a misalignment direction of the first pattern and the second pattern.

It is possible to provide a method for evaluating overlay that can evaluate the amount and direction of misalignment at given positions in an exposure shot.

### BRIEF DESCRIPTION OF THE DRAWINGS

FIGS. 1A and 1B are illustrations of a first embodiment; FIG. 1A shows a scanning electron microscope system, and FIG. 1B shows an overlay evaluation flow;

FIGS. 2A to 2D are schematic diagrams depicting overlay evaluation patterns; FIG. 2A shows an evaluation pattern region including a first and second pattern, FIG. 2B shows the outline of the first pattern, FIG. 2C shows the outline of the second pattern, and FIG. 2D shows the outlines of the first and second pattern arranged at ideal position coordinates;

FIGS. 3A to 3F are illustrations of a layout information registration procedure in the case where given patterns on the wafer are set to an overlay evaluation pattern; FIG. 3A shows a layout information registration flow, FIG. 3B shows a schematic diagram depicting the electron microscope image of an overlay evaluation target pattern, FIG. 3C shows an evaluation target pattern region, FIG. 3D shows the outline of a first pattern, FIG. 3E shows the outline of a second pattern, and FIG. 3F shows the outlines of the first and second pattern arranged at ideal position coordinates;

FIGS. 4A to 4C are illustrations of a layout information registration procedure in the case where a pattern suited for overlay evaluation is automatically selected from design data; FIG. 4A shows a layout information registration flow, FIG. 4B shows an overlay evaluation target pattern selected from design data, and FIG. 4C shows a design layout of a first and second pattern;

FIGS. 5A to 5C are illustrations of a layout information registration procedure in the case where a known overlay evaluation pattern is formed on a wafer according to layout information; FIG. 5A shows a layout information registration flow, FIG. 5B shows an evaluation pattern region including a first and second pattern suited for overlay evaluation, and FIG. 5C shows a design layout of the first and second pattern;

FIGS. 6A to 6D are illustrations of calculating the misalignment amount and direction of patterns; FIG. 6A shows a flowchart of calculating the misalignment amount and direction of patterns, FIG. 6B shows a schematic diagram depicting a scanning electron microscope image including an evaluation target pattern, FIG. 6C shows a comparison diagram between an acquired image and layout information concerning a first pattern, and FIG. 6D shows a comparison diagram between an acquired image and layout information concerning a second pattern;

FIG. 7 is a diagram depicting an exemplary GUI that displays overlay evaluation results;

FIGS. 8A to 8D are illustrations of a method according to a second embodiment that overlay evaluation and length measurement are performed at the same time; FIG. 8A shows an overall flowchart, FIG. 8B shows a schematic diagram depicting the scanning electron microscope image of an overlay evaluation and dimension measurement pattern, FIG. 8C shows a comparison diagram between an acquired image and layout information concerning a first pattern, and FIG. 8D shows a comparison diagram between an acquired image and layout information concerning a second pattern;

FIG. 9 is an overall flowchart of a method according to a third embodiment that overlay evaluation and length measurement are performed at the same time;

FIGS. 10A to 10E are cross sectional views depicting exposure steps illustrative of the double exposure technique; FIG. 10A shows a first resist coating step, FIG. 10B shows an exposure and development step at the first time, FIG. 10C shows a first resist freezing step after the first-time development, FIG. 10D shows a second resist coating step, and FIG. 10E shows an exposure and development step at the second time;

FIGS. 11A and 11B are layout diagrams depicting an overlay evaluation pattern; FIG. 11A shows an arrangement on a wafer, and FIG. 11B shows an arrangement on a chip; and

FIG. 12 is a plan view depicting an exemplary layout of an alignment pattern, automatic focusing pattern, and dimension evaluation pattern.

### DETAILED DESCRIPTION OF THE INVENTION

In the following, an overlay evaluation method for fine patterns using a scanning electron microscope according to the present invention, as an example of charged particle microscopes, will be described with reference to the drawings.

### First Embodiment

For the overlay evaluation method for semiconductor patterns with the scanning electron microscope according to this embodiment, the configuration and overall flow of a scanning electron microscope system will be described, and then individual steps will be described in detail.

Scanning Electron Microscope System

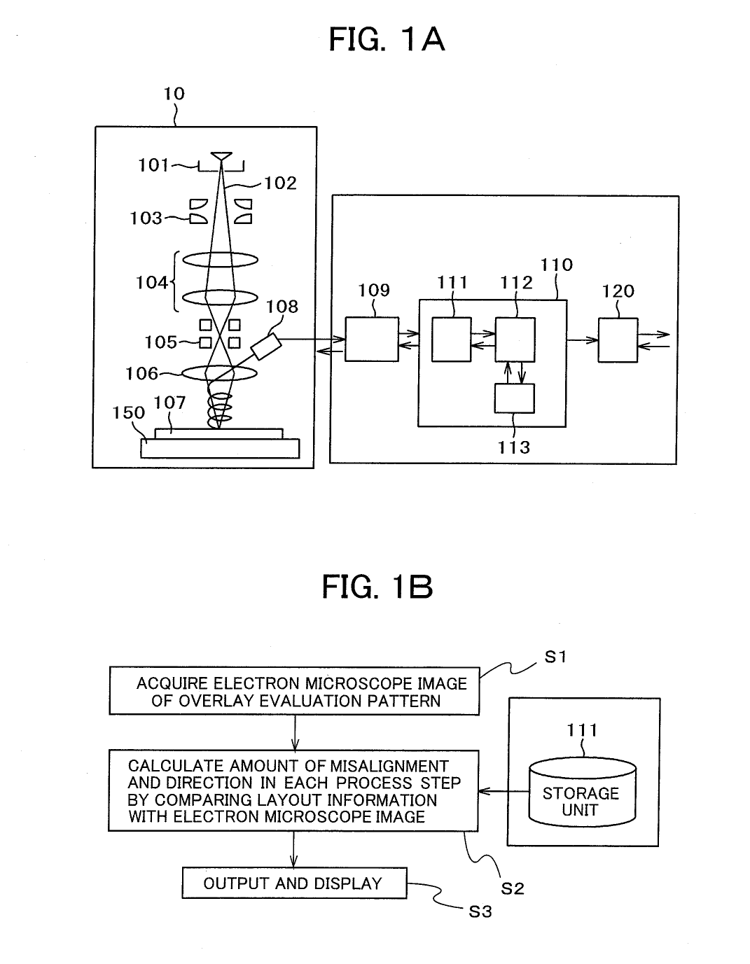

FIG. 1A shows the configuration of a scanning electron microscope system having an overlay evaluation function according to this embodiment. The scanning electron microscope system according to this embodiment includes a scanning electron microscope main body 10, an image processing and overall control unit 109, and a PC 110, and the system is connected to a data server 120 via a network.

The scanning electron microscope (charged particle microscope) main body 10 includes an electron gun (charged particle source) 101, an accelerating electrode 103 that accelerates an electron beam (charged particle beam) 102 emitted from the electron gun 101, a condenser lens 104, a deflection electrode 105 that deflects the track of the electron beam 102, an objective lens 106 that controls the focus position of the electron beam 102 so that the focus position at which the electron beam 102 converges is positioned on the surface of a sample 107 on which patterns are formed, and a detector 108 that partially detects secondary electrons (signals from the sample) generated from the sample 107 onto which the electron beam 102 is applied. The detected signals of this detector 108 are sent to the image processing and overall control unit 109 for processing, and a scanning electron microscope image is then obtained. This scanning electron microscope image is processed at an arithmetic processing unit 112 inside the PC 110 using information stored in a storage unit 111 inside the PC 110, and information concerning overlay is extracted. The result is sent to the data server 120 via communication lines for storage.

The sample 107 is placed on a table (sample stage) 150, and the table 150 is controlled by the image processing and overall control unit 109 so that a desired region on the sample is located in the application region of the electron beam 102.

The PC 110 includes the storage unit 111, the arithmetic processing unit 112, and an input/output unit 113 having a display screen.

Overall Flow

FIG. 1B shows the overall flow of overlay evaluation performed at the arithmetic processing unit 110.

S1: the scanning electron microscope main body 10 is used to take the image of an overlay evaluation pattern formed on the sample 107, and the signals resulted from imaging are processed at the image processing and overall control unit 109 for acquiring a scanning electron microscope image.

S2: in the arithmetic processing unit 112, layout information of the evaluation pattern, which is registered in advance in the storage unit 111, is checked against the acquired scanning electron microscope image for calculating the misalignment amount and direction of the patterns in the individual process (exposure) steps.

S3: the calculated misalignment amount and direction of the patterns in the individual process (exposure) steps are displayed on the input/output unit 113.

The process steps above are the overall flow of overlay evaluation. The detail of each flow will be described below.

Overlay Evaluation Pattern

The detail of the patterns used for overlay evaluation will be described.

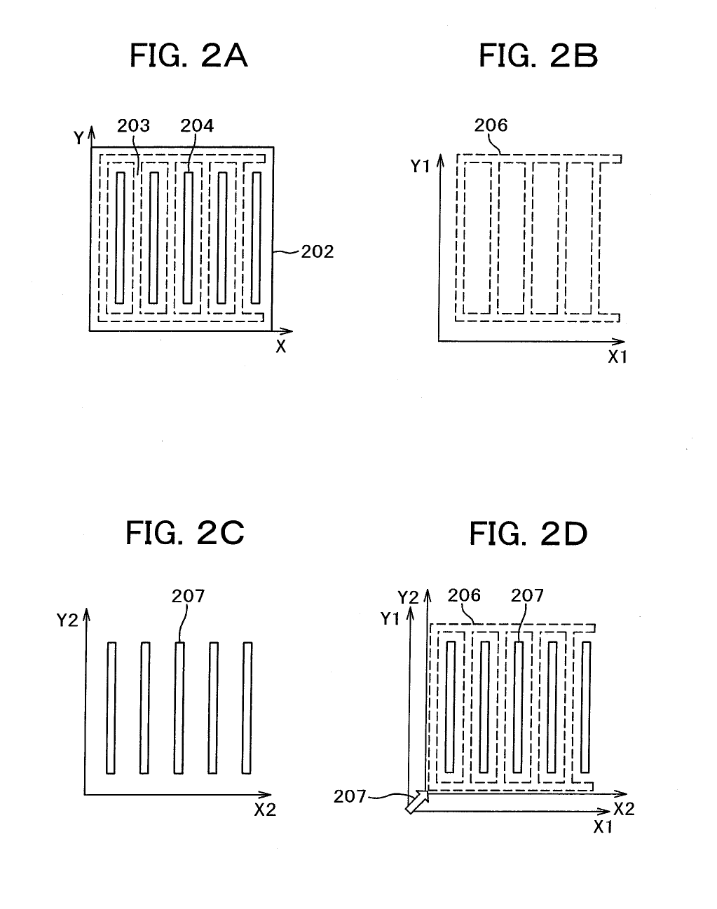

An exemplary overlay evaluation pattern is shown in FIG. 2A. The purpose of this example is to calculate the misalignment amount of the pattern in the X-direction shown in FIGS. 2A to 2D and the angle of the rotational misalignment. The overlay evaluation pattern includes patterns, which are evaluation targets formed in the individual process steps, in a region (evaluation pattern region) 202. The example shown in FIG. 2A includes two patterns, a pattern 203 (referred to as a first pattern below) with a first-time exposure in the double exposure process and a pattern 204 (referred to as a second pattern below) with a second-time exposure.

Moreover, the first pattern 203 includes patterns different in shapes from the second pattern 204. Furthermore, the overlay evaluation pattern includes patterns other than long, linear patterns that continue in the direction parallel with the misalignment direction that is desired to evaluate.

No limitations are placed on the size of patterns. However, since patterns with a small line width and pitch generally have a small process margin and have importance of process management, it is desirable that patterns have a similar pitch in the case where the patterns are formed in processing at a minimum pitch of 90 nm. In this case, in the overlay evaluation pattern as shown in FIG. 2A, the size of the pattern region 202 is about 400 nm square, allowing a reduction in size to a fraction of the conventional size (a few micrometers or more).

In the case of evaluating the misalignment amount of the pattern in the Y-direction shown in FIGS. 2A to 2D, such a pattern is used that the pattern shown in FIG. 2A is rotated at an angle of 90 degrees. Moreover, in the case where the amounts of pattern misalignment in the X- and Y-direction shown in FIGS. 2A to 2D are evaluated at the same time, such a pattern is used that this pattern includes the pattern shown in FIG. 2A and the pattern that the pattern shown in FIG. 2A is rotated at an angle of 90 degrees.

In addition, in this embodiment, the pattern with the first-time exposure in the double exposure process is the first pattern and the pattern with the second-time exposure is the second pattern. However, the first and second pattern may each include a combination of an upper layer pattern and a lower layer pattern.

Content of Layout Information

The detail of the layout information of the overlay evaluation pattern, which is used in Step S2 in FIG. 1B and registered in the storage unit 111, will be described.

The following is information necessary for overlay evaluation: pattern shapes; process step information about each part of the patterns (identification between the first pattern and the second pattern); the ideal positional relationship or distance between the patterns to be formed in the individual process steps; and the position coordinates of the evaluation pattern on the wafer and in the shot.

When the overlay evaluation pattern shown in FIG. 2A is taken as an example, the following is registered as layout information as shown in FIGS. 2B, 2C, and 2D: an outline 206 of the first pattern; an outline 207 of the second pattern; and ideal relative position coordinates 208 of the second pattern with respect to the first pattern.

Layout Information Registration Procedure

A procedure that registers these items of layout information in the storage unit 111 of the scanning electron microscope system will be described. For the procedure, three cases will be described. Case 1: given patterns on the wafer are set to the overlay evaluation pattern. Case 2: a pattern suited for overlay evaluation is automatically selected from design data. Case 3: a known overlay evaluation pattern is formed on a wafer in advance according to layout information.

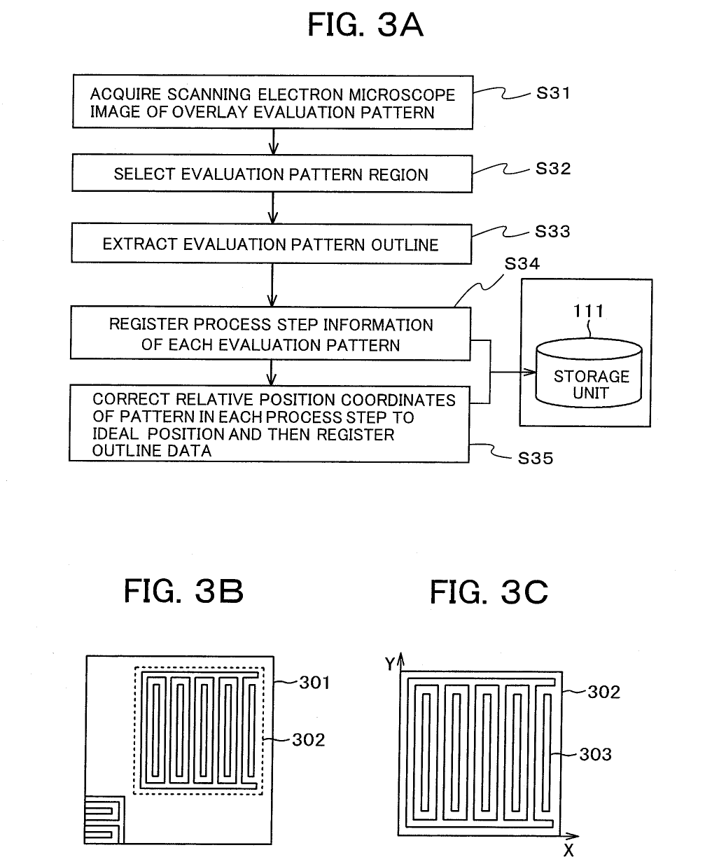

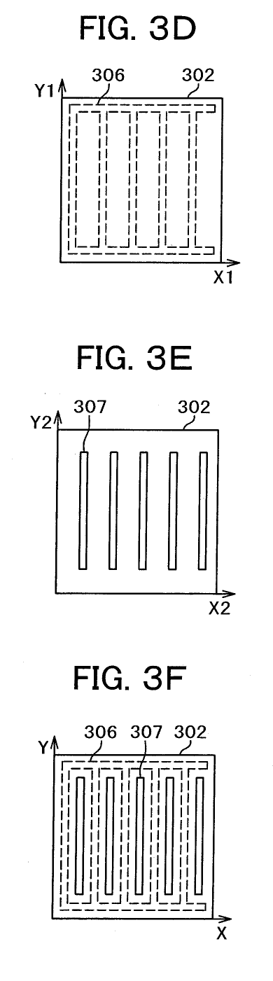

Case 1: a layout information registration flow is shown in FIG. 3A in the case where given patterns on the wafer are set to an overlay evaluation pattern.

S31: as shown in FIG. 3B, a scanning electron microscope image 301 that includes patterns desired to be an overlay evaluation target is acquired. Because the shooting target is a resist pattern, the image is acquired under the shooting conditions in consideration of damage to both of the resist and the sample. For example, the accelerating voltage of primary electrons to be applied to the sample is set to 500 V. In addition, because the size of the overlay evaluation pattern region is about 400 nm square, the size of the imaging field is set so as to exceed this size, and the image is taken so that the pixel size is about a nanometer square in order to acquire the pattern with a sharpened outline.

S32: an evaluation target pattern region 302 is selected from the acquired image.

S33: as shown in FIG. 3C, in the selected evaluation target pattern region 302, an outline 303 of the pattern is extracted. The methods of extracting the outline include a method that a user determines the outline using the input/output unit 113 and also include a means for automatically extracting the outline in the arithmetic processing unit 112.

S34: as shown in FIGS. 3D and 3E, patterns in the individual outlines 303 are registered in each process step, so that a first pattern 306 and a second pattern 307 are identified and stored. The registration method is that the user specifies a process step for each pattern with respect to outline data shown on a GUI (Graphical User Interface) for registration.

S35: outline data (FIG. 3F) that coordinates are corrected is registered in the storage unit 111 so that the patterns (306 and 307) in the individual registered process steps are in an ideal positional relationship relative to each other.

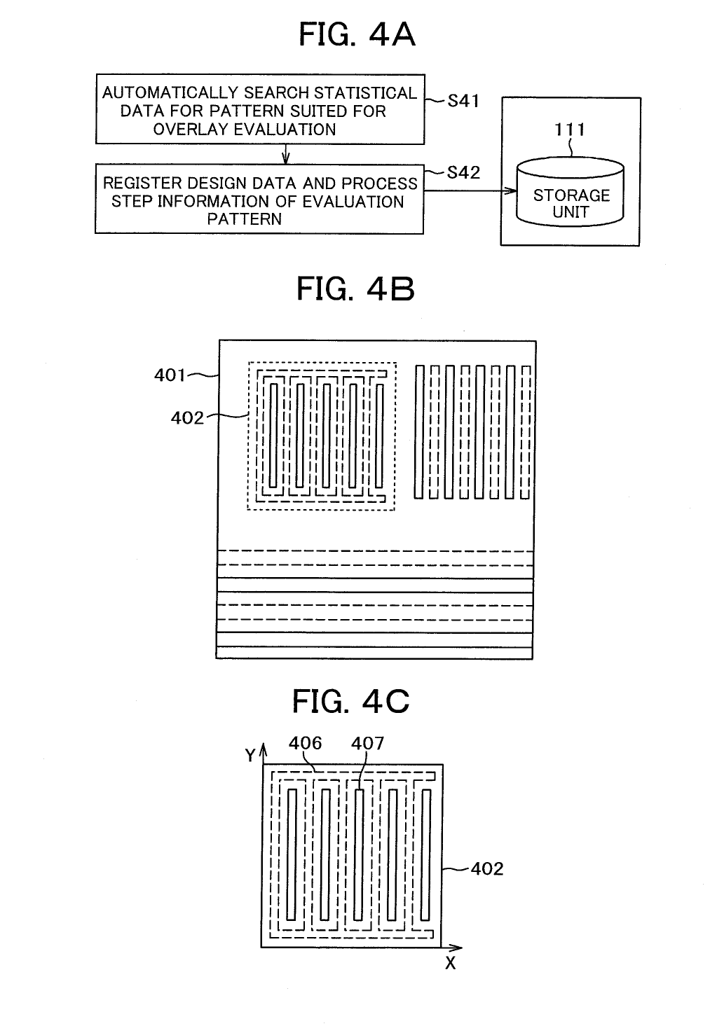

Case 2: FIG. 4A shows a layout information registration flow in the case where a pattern suited for overlay evaluation is automatically selected from design data.

S41: as shown in FIG. 4B, an evaluation pattern region 402 including patterns suited for overlay evaluation is automatically selected from design data 401 for plural process steps to be evaluation targets. In automatically selecting the region 402, the patterns in the plurality of process steps that are pre-specified evaluation targets are searched for the pattern suited for overlay evaluation in the pre-specified search area of design data. The detail of the pattern suited for overlay evaluation is as described in the aforementioned section of Overlay Evaluation Pattern. In addition to this, it is also possible to provide search conditions such as the size of suitable evaluation patterns, the size of the evaluation pattern region, or the direction to be an evaluation target.

S42: the design data of the overlay evaluation pattern (including the first pattern outline 406, the second pattern outline 407, position information of each pattern, or the like; see FIG. 4C) selected in Step S41 is registered in the storage unit 111 for each pattern in the individual process steps.

In addition, it is also possible that the user freely selects patterns from design data instead of automatically selecting the pattern suited for overlay evaluation in Step S41.

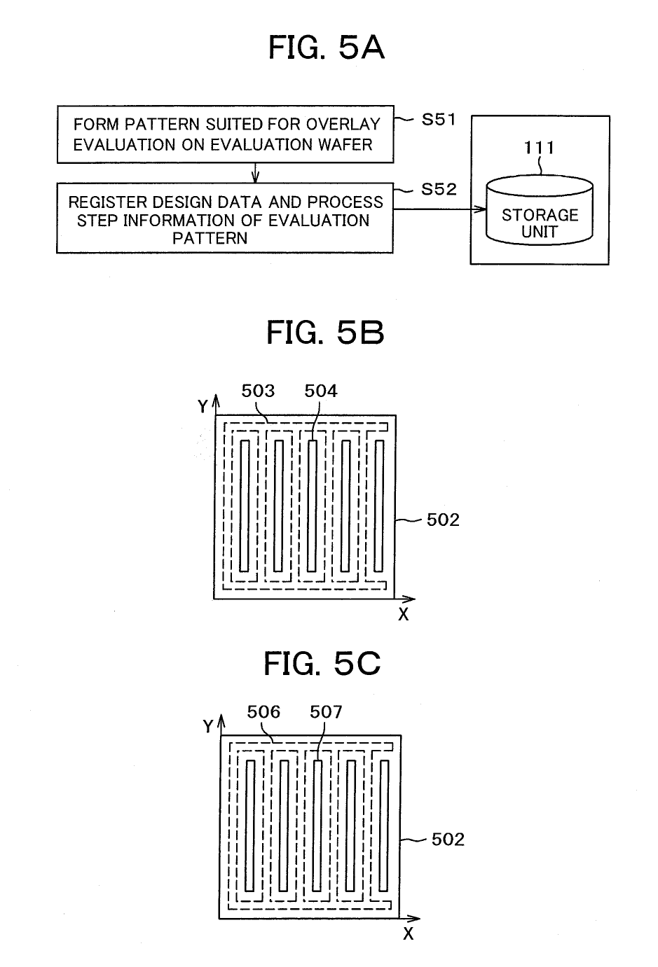

Case 3: FIG. 5A shows a layout information registration flow in the case where a known overlay evaluation pattern is formed on a wafer in advance according to layout information.

S51: as shown in FIG. 5B, an evaluation pattern region 502 including a first pattern 503 and a second pattern 504, which are suited for overlay evaluation, are formed on an evaluation wafer in each process step. The detail of the pattern suited for overlay evaluation is as described in the aforementioned section of Overlay Evaluation Pattern.

S52: the design data of the overlay evaluation pattern formed on the wafer in Step S51 (including a first pattern outline 506, a second pattern outline 507, position information of each pattern, or the like; see FIG. 5C) is registered in the storage unit 111 for each pattern in the individual process steps.

With the aforementioned methods, the layout information of the overlay evaluation pattern is registered in advance in the storage unit 111.

Calculation of Misalignment Amount and Direction of the Pattern

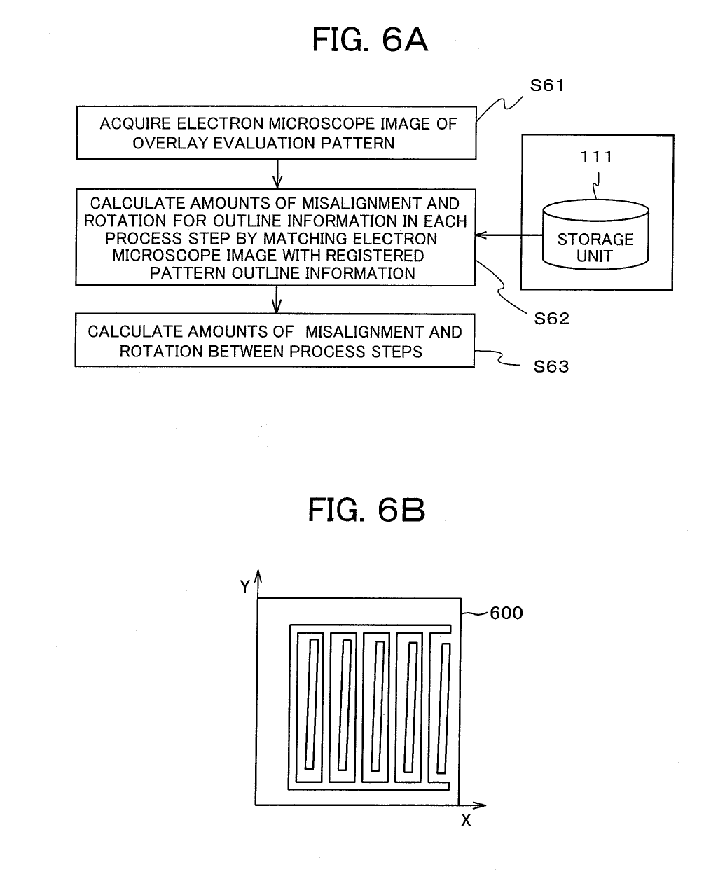

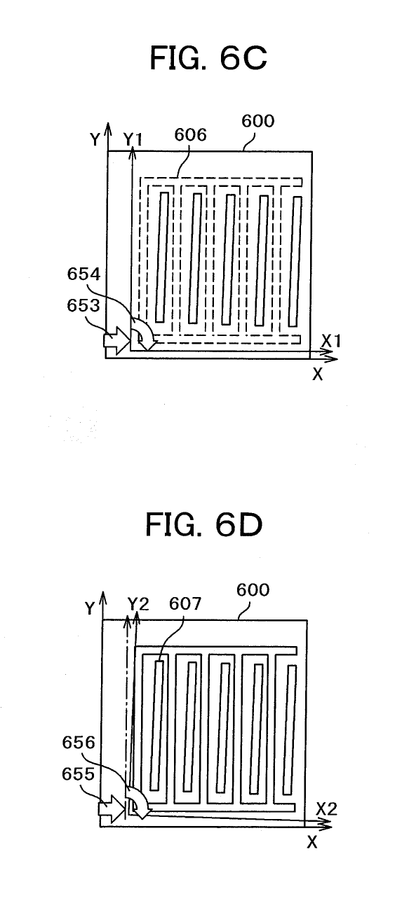

FIG. 6A shows a flow of calculating the misalignment amount and direction of the patterns in Step S2 in FIG. 1B.

S61: as shown in FIG. 6B, a scanning electron microscope image 600 including an evaluation target pattern is acquired. Because the shooting target is the resist, the image is acquired under the shooting conditions in consideration of damage to both of the resist and the sample. For example, the accelerating voltage of primary electrons to be applied to the sample is set to 500 V. In addition, since the size of the overlay evaluation pattern is about 400 nm square, the size of the imaging field is set so as to exceed this size, and the image is taken so that the pixel size is about a nanometer square in order to acquire the pattern with a sharpened outline. (The same as in Step S31.)

S62: as shown in FIGS. 6C and 6D, the acquired scanning electron microscope image 600 is matched against pattern shape information (a first pattern outline 606 and a second pattern outline 607) in each process step registered in the storage unit 111, and misalignment amounts dX1 (653) and dX2 (655) and rotation amounts dθ1 (654) and dθ2 (656) in the scanning electron microscope image are calculated with respect to pattern shape information in the individual registered process steps.

S63: according to Equations (1) and (2), the misalignment amount dX, the misalignment direction, the rotation amount dθ, and the rotation direction, which are relative to each other in the process steps, are calculated.

dX=dX2−dX1 (1)

Where dX>0, the second pattern is displaced on the right with respect to the first pattern by |dX|.

Where dX≦0, the second pattern is displaced on the left with respect to the first pattern by |dX|.

dθ=dθ2−dθ1 (2)

Where dθ>0, the second pattern is rotated clockwise with respect to the first pattern by |dθ|.

Where dθ≦0, the second pattern is rotated counterclockwise with respect the first pattern by |dθ|.

From the steps described above, it was possible to describe the directions of misalignment and rotation as well as the amounts of misalignment and rotation of the second pattern with respect to the first pattern.

Layout of the Overlay Evaluation Pattern

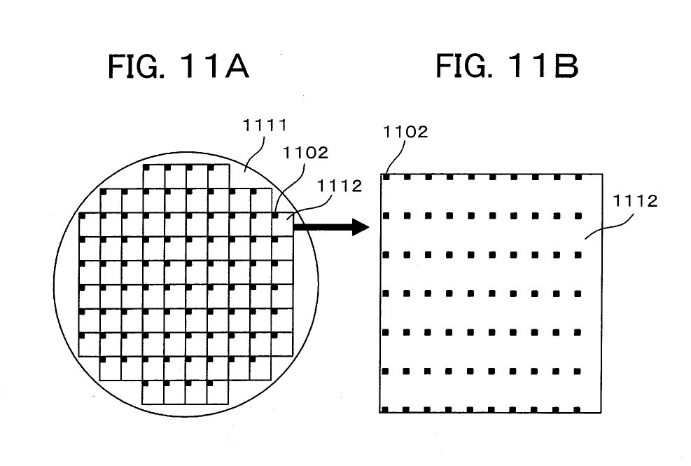

FIGS. 11A and 11B show an exemplary overlay evaluation pattern layout on a wafer and chips in performing overlay evaluation.

In order to evaluate the overlay accuracy of an exposure system, an overlay evaluation pattern region 1102 is set on each chip on a wafer 1111 for evaluation as shown in FIG. 11A. In the case where the amount of overlay misalignment or the direction of misalignment is different on the wafer surface, it is expected to improve overlay accuracy by feeding back the result to the shot position correction of the exposure system.

In order to perform overlay evaluation in a shot according to the aberration of the exposure system and the transfer characteristics due to mask design, plural overlay evaluation pattern regions 1102 are set in each of the chips 1112, which are exposed with the same shot, for evaluation as shown in FIG. 11B. Because the size of the overlay evaluation pattern region 1102 explained in this embodiment is about 400 nm square, even if a region having plural overlay evaluation pattern regions is formed on a chip with sides of about a few centimeters, the influence on integration density can be made smaller. In addition, because aberration correction is performed in a single shot, it is sufficient to form evaluation pattern regions in each of plural chips in distribution if a plurality of chips are exposed with a single shot, and it is possible to reduce the number of evaluation pattern regions per chip.

GUI (Graphical User Interface)

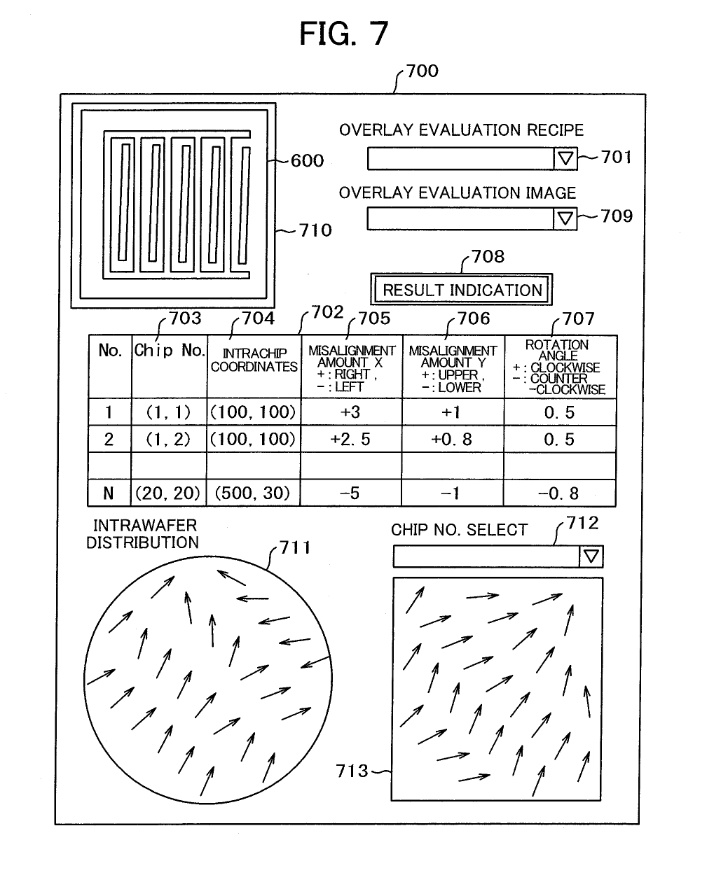

FIG. 7 shows an exemplary GUI representing overlay evaluation results that are displayed on the input/output unit 113 of the scanning electron microscope system in Step S3 in FIG. 1B.

An overlay evaluation recipe select button 701 on a display screen 700 is used to select a data set that is desired to display results, a result indication button 708 is pressed down, and then results are outputted to a table 702. The table 702 includes a chip number 703 of each item of data, intrachip coordinates 704, a misalignment amount 705 for the second pattern with respect to the first pattern in the X-direction, a misalignment amount 706 in the Y-direction, and a rotation angle 707. Moreover, an overlay evaluation image select button 709 is used to select an image that is desired to display, and then a scanning electron microscope image and layout information are displayed on an image display area 710.

Furthermore, based on the results, an overlay misalignment amount distribution 711 on the wafer surface is displayed. In addition, a chip number select button 712 on the display screen is used to select a chip, and then an overlay misalignment amount distribution 713 on this chip is displayed. The chip number select button 712 is used to select a particular chip as well as to select representation of an average distribution of chips. Moreover, in display of the screen, FIG. 7 shows the image display area 710, the table 702, the overlay misalignment amount distribution 711 on the wafer surface, the overlay misalignment amount distribution 713 on the chip, or the like on a single screen. However, these methods may be possible that one result is displayed on one screen, two results on one screen, and three results on one screen.

The scanning electron microscope is used to allow overlay evaluation in a micro region, so that it is made possible to evaluate the overlay misalignment amount distribution on the chip as well as on the wafer surface. It is possible to correct the alignment error of the exposure system based on the evaluated result on the wafer surface. In addition, it is possible to perform the aberration correction of the exposure system based on the evaluated result on the chip. It is made possible to perform misalignment correction on the chip by optimizing the exposure process conditions, and it is possible to expect an improved yield in the semiconductor fabrication processes.

In this embodiment, outline information is taken as an example of pattern shape information. However, it is also possible to replace the outline with a pattern region or the center coordinates of the pattern.

It is also possible that the overlay evaluation pattern explained in this embodiment also serves as a pattern dimension evaluation pattern or pattern shape evaluation pattern. In addition, it is also possible that the overlay evaluation pattern also serves as an automatic focusing pattern, alignment pattern, or the like, which is necessary in automatic dimension measurement sequences using the scanning electron microscope.

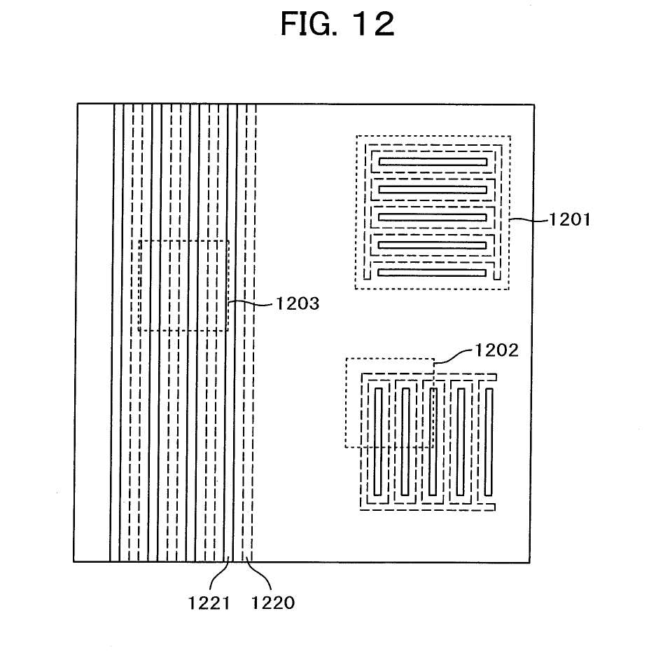

An exemplary layout is shown in FIG. 12. In automatic dimension measurement, first, the imaging field is moved to an alignment pattern 1201 to calibrate coordinate positions more highly accurately. Subsequently, an automatic focusing pattern 1202 is focused, and then the imaging field is moved to dimension evaluation coordinates 1203 for imaging and dimension measurement. In this sequence, it is possible to perform overlay evaluation at the same time using an image acquired in automatic focusing, or image acquired for alignment. In addition, a pattern 1220 indicated by a broken line is a pattern formed with a first-time exposure, and a pattern 1221 indicated by a solid line is a pattern formed with a second-time exposure.

As discussed above, patterns (semiconductor patterns) used in fabricating semiconductor integrated circuit devices are taken and explained as an example. However, it is effective to apply this method to overlay evaluation in the DP process for forming a gate pattern, which pattern density is higher and dimensions management accuracy is also critical particularly. In the DP process for forming the gate, the main pattern at the first and second time exposure is often a repeat pattern, and it is necessary to select a pattern in suited design in advance so that patterns are different between the first and second pattern for overlay evaluation in order to determine the direction of misalignment. In addition, it is also possible to use this method for overlay evaluation of fine patterns, not limited to semiconductor patterns.

According to this embodiment, it is possible to provide a method for evaluating overlay that can evaluate the amount and direction of misalignment at given positions in an exposure shot. Thus, it is made possible to perform highly accurate overlay management by feeding back the evaluated result to the exposure process. In addition, it is possible to provide a charged particle microscope that is suited for overlay evaluation and can readily obtain the evaluated results of the amount and direction of overlay misalignment.

### Second Embodiment

In terms of the method that performs the overlay evaluation of semiconductor patterns with the scanning electron microscope according to the method explained in the first embodiment and the dimension measurement of semiconductor patterns with the scanning electron microscope at the same time, the overall flow will be described and then the individual steps will be described in detail. In addition, the items that are described in the first embodiment and not described in this embodiment are the same as those in the first embodiment.

Overall Flow

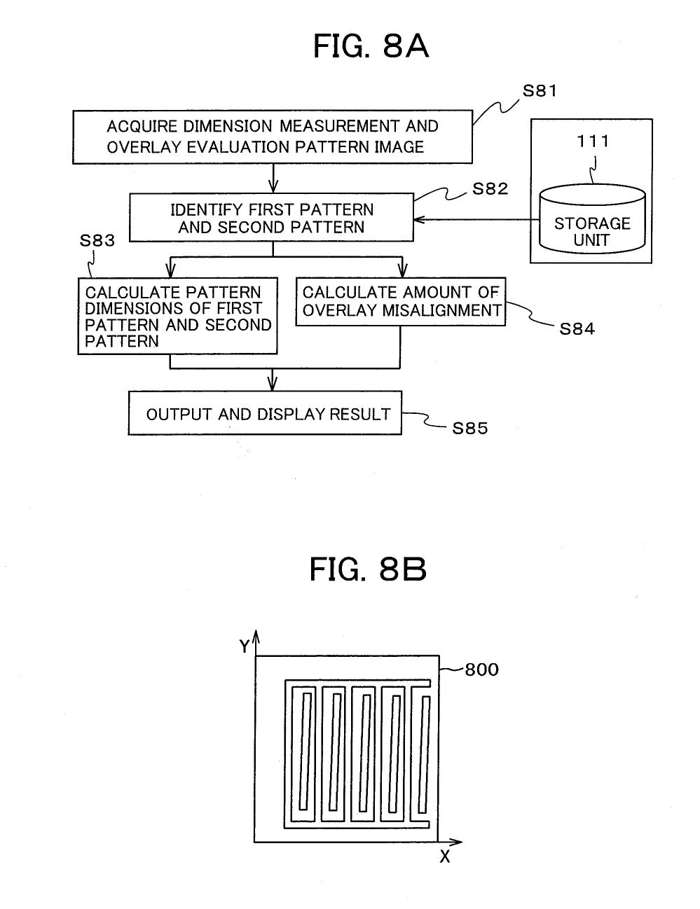

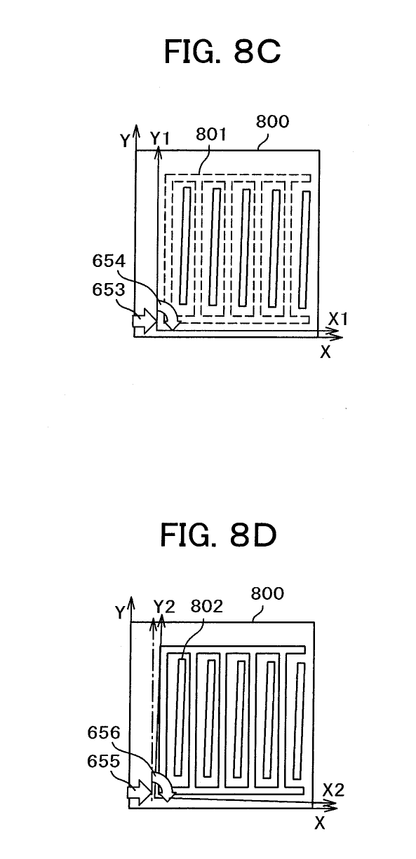

FIG. 8A shows an overall flow in the case where dimension measurement and overlay evaluation are performed at the same time, which are performed with the scanning electron microscope 10.

S81: the scanning electron microscope 10 is used to take the image of a dimension measurement pattern that also serves as the overlay evaluation pattern, the signals resulted from imaging are processed at the image processing and overall control unit 109, and then a scanning electron microscope image 800 shown in FIG. 8B is acquired. Because the shooting target is a resist, the image is acquired under the shooting conditions in consideration of damage to both of the resist and the sample. For example, the accelerating voltage of primary electrons to be applied to the sample is set to 500 V. In addition, because the size of the dimension measurement pattern that also serves as the overlay evaluation pattern is about 400 nm square, the size of the imaging field is set so as to exceed this size, and the image is taken so that the pixel size is about a nanometer square in order to acquire the pattern with a sharpened outline.

S82: in the arithmetic processing unit 112, the layout information of the evaluation pattern, which is registered in advance in the storage unit 111, is checked against the scanning electron microscope image for identifying the patterns in the individual process steps as shown in a first pattern 801 and a second pattern 802 in FIGS. 8C and 8D.

S83: the dimensions of the identified patterns in the individual process steps are measured.

S84: at the same time in Step S83, the scanning electron microscope image of the identified patterns in the individual process steps is checked against the layout information of the evaluation pattern, which is registered in advance in the storage unit 111, for calculating the misalignment amount and direction of the patterns in the individual process steps.

S85: the calculated pattern dimensions, overlay misalignment amount, and misalignment direction in the individual process steps are displayed on the input/output unit 113.

The discussion above is the overall flow of the dimension measurement procedure that also serves as overlay evaluation. The detail of each flow will be described below.

Dimension Measurement Pattern That also Serves as the Overlay Evaluation Pattern

The detail of the dimension measurement pattern that also serves as the overlay evaluation pattern will be described. Suppose that this pattern satisfies the conditions for the overlay evaluation pattern in the first embodiment in terms of the types of patterns, the dimensions of which should be measured for process management in the pattern fabrication process.

An exemplary pattern is shown in FIG. 8B. In the example shown in FIG. 8B, the pattern is a high density pattern in which the pattern pitch in each process has a relatively small process margin in the fabrication process of this pattern. At the same time, because this pattern satisfies the conditions for the overlay evaluation pattern in the first embodiment, it can be said that this pattern is the dimension measurement pattern that also serves as the overlay evaluation pattern. Because the sections of Layout Information, Layout Information Registration Procedure, Calculation of Misalignment Amount and Direction of the Patterns, and GUI overlap with the description explained in the first embodiment, the explanation is omitted.

According to this embodiment, it is possible to obtain the same effect as that of the first embodiment. In addition, the dimension measurement and overlay evaluation of the patterns are performed at the same time. Thus, it is made possible to perform the process steps up to overlay evaluation for the same duration for which conventional dimension measurement is performed, and it is made possible to perform measurement that identifies the patterns in the individual process steps also in dimension measurement.

### Third Embodiment

Overlay Evaluation and Length Measurement with the Alignment Mark

In terms of the method that performs the overlay evaluation of semiconductor patterns with the scanning electron microscope according to the method explained in the first embodiment and the dimension measurement of semiconductor patterns with the scanning electron microscope at the same time, the overall flow will be described and then the individual steps will be described in detail. In addition, the items that are described in the first embodiment and not described in this embodiment are the same as those in the first embodiment.

Overall Flow

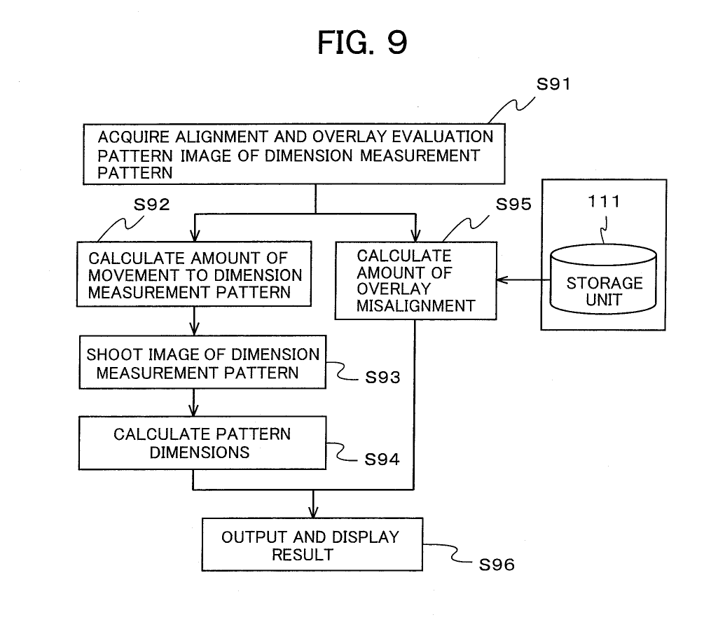

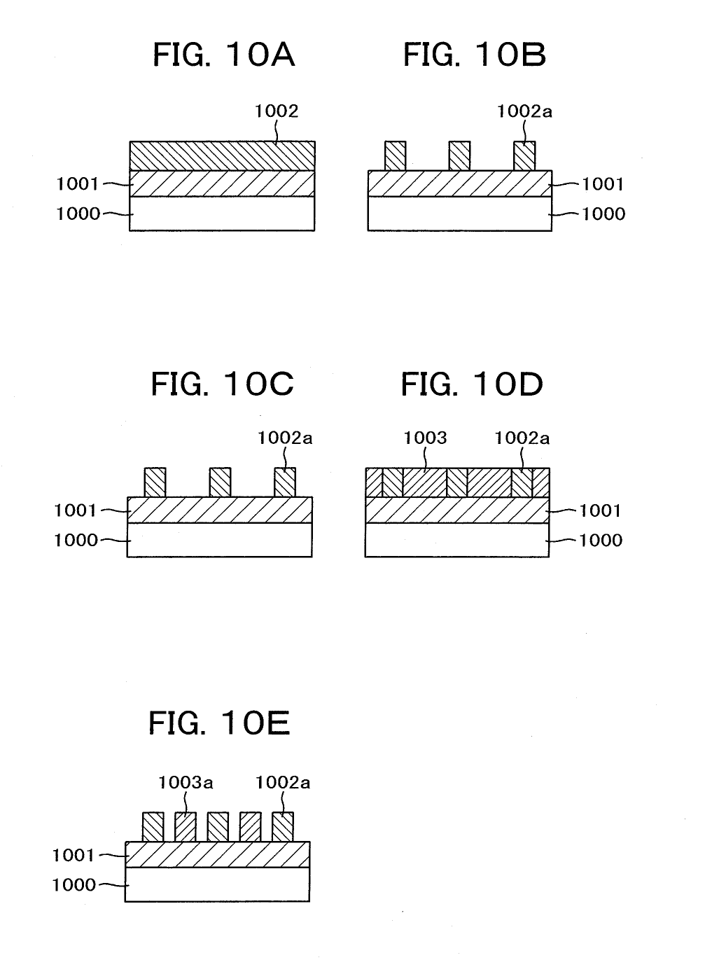

FIG. 9 shows an overall flow in the case where dimension measurement and overlay evaluation are performed at the same time, which are performed with the scanning electron microscope 10.

S91: the scanning electron microscope 10 is used to take the image of the alignment pattern for the dimension measurement pattern that also serves as the overlay evaluation pattern, and the signals resulted from imaging are processed at the image processing and overall control unit 109 for acquiring a scanning electron microscope image. Because the shooting target is the resist, the image is acquired under the shooting conditions in consideration of damage to both of the resist and the sample. For example, the accelerating voltage of primary electrons to be applied to the sample is set to 500 V. In addition, the imaging field is set in consideration of alignment accuracy before alignment, and the image is taken so that the pixel size is about a nanometer square in order to acquire the pattern with a sharpened outline.

S92: the relationship between the imaging coordinates in Step S91 and the pattern positions of the imaged scanning electron microscope image is evaluated, and the amount of movement to the dimension measurement pattern, which is registered in advance, is calculated.

S93: based on the calculated result in Step S92, the imaging field is moved to the imaging position of the dimension measurement pattern for taking the image of the dimension measurement pattern, and the signals resulted from imaging are processed at the image processing and overall control unit 109 for acquiring a scanning electron microscope image.

S94: the dimensions of the dimension measurement pattern are measured from the scanning electron microscope image acquired in Step S93.

S95: at the same time in Steps 92 to S94, the scanning electron microscope image of the alignment pattern for the dimension measurement pattern that also serves as the overlay evaluation pattern and is acquired in Step S91 is checked against the layout information of the evaluation pattern, which is registered in advance in the storage unit 111, at the arithmetic processing unit 112 for calculating the misalignment amount and direction of the patterns in the individual process steps.

S96: the calculated pattern dimensions, overlay misalignment amount, and misalignment direction in the individual process steps are displayed on the input/output unit 113.

The discussion above is the overall flow of the dimension measurement procedure that also serves as overlay evaluation. The detail of each flow will be described below.

Alignment Pattern for the Dimension Measurement Pattern that also Serves as the Overlay Evaluation Pattern

The detail of the alignment pattern for the dimension measurement pattern that also serves as the overlay evaluation pattern will be described. Suppose that this pattern satisfies the conditions for the overlay evaluation pattern in the first embodiment in terms of the pattern suited for pattern matching for alignment of the dimension measurement pattern. An exemplary pattern is shown in FIG. 2A. The conditions of the pattern suited for pattern matching are the conditions similar to the conditions for the overlay evaluation pattern such as a condition that a unique pattern exists other than the repeat pattern and a condition that a pattern exists other than the pattern continuing in the same direction with respect to the moving direction of the dimension measurement pattern. Thus, the conditions have a feature that the overlay evaluation pattern tends to be selected for the alignment pattern for the dimension measurement pattern. Because the sections of Layout Information, Layout Information Registration Procedure, Calculation of Misalignment Amount and Direction of the Patterns, and GUI overlap with the description explained in the first embodiment, the explanation is omitted.

In this embodiment, the procedure is explained in which the alignment pattern for the dimension measurement pattern and the overlay evaluation pattern are combined. However, it is also possible that the overlay evaluation pattern also serves as other image acquiring patterns necessary for pattern dimension measurement with the scanning electron microscope, in addition to the alignment pattern for the dimension measurement pattern.

According to this embodiment, it is possible to obtain the same effect as that of the first embodiment. In addition, the dimension measurement and overlay evaluation of the patterns are performed at the same time. Thus, it is made possible to perform the process steps up to overlay evaluation for the same duration for which conventional dimension measurement is performed.

### REFERENCE SIGNS LIST

10 . . . scanning electron microscope main body
101 . . . electron gun
102 . . . electron beam
103 . . . accelerating electrode
104 . . . condenser lens
105 . . . deflection electrode
106 . . . objective lens
107 . . . sample
108 . . . detector
109 . . . image processing and overall control unit
110 . . . PC
111 . . . storage unit
112 . . . arithmetic processing unit
113 . . . input/output unit
120 . . . data server
150 . . . table (sample stage)
202,302,502,1102 . . . evaluation pattern region
203,503 . . . first pattern
204,504 . . . second pattern
206, 306, 406, 506, 606 . . . first pattern outline
207,307,407,507,607 . . . second pattern outline
600,800 . . . scanning electron microscope image
653,655 . . . misalignment amounts in X-direction
654,656 . . . rotation amounts
700 . . . display screen
701 . . . overlay evaluation recipe select button
708 . . . result indication button
709 . . . overlay evaluation image select button
710 . . . image display area
711 . . . overlay misalignment amount distribution on wafer surface
712 . . . chip number select button
713 . . . overlay misalignment amount distribution on chip
1000,1111 . . . wafer (substrate)
1001 . . . lower layer film
1002 . . . first resist film
1002a . . . resist pattern with first-time exposure
1003 . . . second resist film
1003a . . . resist pattern with second-time exposure
1112 . . . chips

What is claimed is:

1. A method for evaluating overlay of patterns using a first pattern formed on a sample in a first exposure step and a second pattern formed on the sample in a second exposure step, the method comprising:
registering, in a database, layout information about the first pattern and the second pattern to be arranged;
acquiring an image of the first pattern and the second pattern formed on the sample with a charged particle microscope; and
comparing the layout information registered in the database with the image and determining a misalignment amount and a misalignment direction of the first pattern and the second pattern.

2. The method for evaluating overlay of patterns according to claim 1,
wherein the layout information includes outline data that is determined and corrected through:
acquiring an image of the first pattern and the second pattern formed in advance with a charged particle microscope;
selecting an evaluation pattern region including the image;
extracting outlines of the first pattern and the second pattern; and
correcting relative position coordinates of the first pattern and the second pattern to an ideal position.

3. The method for evaluating overlay of patterns according to claim 1,
wherein the layout information includes information selected from design data of the first pattern and the second pattern.

4. The method for evaluating overlay of patterns according to claim 3,
wherein the selection is made by automatic selection from the design data of the first pattern and the second pattern.

5. The method for evaluating overlay of patterns according to claim 1,
wherein the layout information includes shape information about the first pattern and the second pattern, process step information, and target relative position information between the first pattern and the second pattern.

6. The method for evaluating overlay of patterns according to claim 1,
wherein at least one of the first pattern and the second pattern also serves as a dimension measurement pattern to perform dimension evaluation as well as overlay evaluation.

7. The method for evaluating overlay of patterns according to claim 1,
wherein at least one of the first pattern and the second pattern also serves as an alignment pattern for a dimension measurement pattern to perform dimension evaluation as well as overlay evaluation by determining a position of the dimension measurement pattern based on a position of the alignment pattern.

8. A charged particle microscope comprising:
a charged particle source;
a deflection electrode configured to deflect a charged particle emitted from the charged particle source;
a sample stage configured to place a sample thereon, the sample having an overlay evaluation pattern formed in a first exposure step and a second exposure step;
a detector configured to detect a signal from the evaluation pattern by applying the charged particle to the evaluation pattern;
an image processing and overall control unit configured to acquire an image by processing the detected signal from the detector;
a storage unit configured to register therein layout information of the overlay evaluation pattern;
an arithmetic processing unit configured to perform calculation using the image and the layout information; and
an input/output unit having a display screen configured to display thereon information including an overlay misalignment amount and a misalignment direction in the first exposure step and the second exposure step based on a calculated result at the arithmetic processing unit.

9. The charged particle microscope according to claim 8,
wherein the layout information includes shape information about the overlay evaluation pattern, process step information, and position information.

10. The charged particle microscope according to claim 8,
wherein the input/output unit has an overlay evaluation recipe selecting function and an overlay evaluation image selecting function.

11. The charged particle microscope according to claim 8, wherein:
the sample is a wafer having a plurality of regions of chips; and
the input/output unit has a selecting function that displays an overlay misalignment amount distribution on a surface of the wafer on the display screen and a chip selecting function that displays an overlay misalignment amount distribution on a surface of the chip on the display screen.

12. The charged particle microscope according to claim 8,
wherein the overlay evaluation pattern includes a first pattern formed in the first exposure step and a second pattern formed in the second exposure step.

13. The charged particle microscope according to claim 12,
wherein the first pattern and the second pattern are different in shape.

14. The charged particle microscope according to claim 8,
wherein the overlay evaluation pattern also serves as a dimension measurement pattern, and a measured result of the dimension measurement pattern is displayed on the display screen.

15. The charged particle microscope according to claim 8,
wherein the overlay evaluation pattern also serves as a dimension measurement alignment pattern, and a dimension measurement result is displayed on the display screen.
